(19) United States
(12) Patent Application Publication
(10) Pub. No.: US 2008/0094115 A1
(43) Pub. Date: Apr. 24, 2008

(54) DLL circuit

(75) Inventor: Toru Ishikawa, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/907,159

(22) Filed: Oct. 10, 2007

(30) Foreign Application Priority Data
Oct. 12, 2006 (JP) 2006-278773

(51) Int. Cl. H03L 7/087; H03L 7/08

(52) U.S. Cl. 327/158

(57) ABSTRACT

A DLL circuit has a rise delay adjustment circuit and a fall delay adjustment circuit. The fall delay adjustment circuit is supplied with a clock adjusted on a rise side in the rise delay adjustment circuit. Since the clock supplied to the fall delay adjustment circuit has already been adjusted on the rise side, a delay difference on a fall side is very small. Therefore, the fall delay adjustment circuit and a fall counter can be drastically reduced in circuit scale. As a consequence, it is possible to obtain the DLL circuit having a small circuit scale and high accuracy.

This application is based upon and claims the benefit of priority from Japanese patent application No. 2006-278773, filed on Oct. 12, 2006, the disclosure of which is incorporated herein in its entirety by reference.

### BACKGROUND OF THE INVENTION

This invention relates to a DLL (Delay Lock Loop) circuit and, in particular, to a DLL circuit for generating an internal clock synchronized with rise and fall of an external clock signal.

A recent electronics system is increased in operation speed and a data transfer rate between semiconductor devices constructing the system is drastically increased. Therefore, each of the semiconductor devices is also required to perform a high-speed data transfer operation and, inside the semiconductor device, use is made of a clock synchronization method in which synchronization of the semiconductor device is established by the use of a clock. Such a semiconductor device is a synchronous semiconductor device. Further, in recent years, a growing number of systems use a DDR (Double Data Rate) interface in which data are outputted in synchronization with rise and fall of a clock signal.

For example, in case of a DRAM (Dynamic Random Access Memory), DDR1, DDR2, DDR3, and so on operated with the DDR interface are produced as commercial products. In those products with the DDR interface, a DLL (Delay Lock Loop) circuit is generally used in order to generate an internal clock synchronized with an external clock. In those products, data transfer rates are as high as 400 MHz, 800 MHz, and 1.6 GHz in DDR1, DDR2, and DDR3, respectively. In association with the increase in data transfer rate, improvement of clock accuracy of the DLL circuit for use in those products is important.

The DLL circuit is required to have a delay adjustment width corresponding to a time duration not shorter than a clock period in order to establish clock synchronization and to perform a delay adjustment step with high accuracy. For example, in case of a DDR2 product of 533 MHz, it is necessary to cover a clock period ranging from 3.75 to 8 ns. In case where the clock period of 8 ns is covered, a delay adjustment circuit having a delay adjustment width on the order of 10 ns with some margin is generally required. If the delay adjustment is performed by every step of 25 ps, the delay adjustment width of 10 ns corresponds to 400 steps so that a 9-bit counter is required. With respect to delay elements of the delay adjustment circuit, 100 inverters are required in order to cover the delay adjustment width of 10 ns, assuming that each inverter has a delay of 10 ps. Further, a selector group for selecting these inverters is also required. Thus, there is a problem that the DLL circuit is drastically increased in circuit scale. Therefore, the DLL circuit is required to have a high accuracy and to be constructed in a small circuit scale.

The DLL circuit is disclosed in Japanese Unexamined Patent Application Publication (JP-A) No. 2005-51673 (Patent Document 1). The DLL circuit of Patent Document 1 comprises a coarse delay line CDL, a fine delay line FDL, and a counter circuit and each of rise and fall of a clock is independently controlled. An inverter portion of a delay circuit is used in common for rise and fall. However, for each of rise and fall, a selector comprising a NAND or the like, and a coarse delay adjustment circuit are independently required. Basically, an independent delay circuit is formed for each of rise and fall. FIG. 1 shows a simplified illustration of a circuit structure of Patent Document 1 and FIG. 2 shows a time chart of operation thereof.

The DLL circuit shown in FIG. 1 comprises a rise delay adjustment circuit 12, a rise phase comparison circuit 15, a rise counter 14, a fall delay adjustment circuit 20, a fall phase comparison circuit 17, a fall counter 21, a Mux circuit 18 for synthesizing an ultimate or final internal clock, and an output replica circuit 19. The rise and the fall delay adjustment circuits 12 and 20 correspond to a circuit including both of the coarse delay line CDL and the fine delay line FDL of Patent Document 1. Referring also to the operation time chart shown in FIG. 2, the rise and the fall delay adjustment circuits 12 and 20 as independent circuits are supplied with an external clock CLK and produce clocks Clk-R1 and Clk-F1 which are delay-adjusted for rise and fall, respectively.

The Mux circuit 18 is supplied with the clocks Clk-R1 and Clk-F1 obtained by delay adjustment for rise and fall with respect to the external clock CLK, respectively, and synthesizes the clocks to obtain a delay-adjusted clock signal Clk-FB. The clock signal Clk-FB is fed back to the rise and the fall phase comparison circuits 15 and 17. Each of the rise and the fall phase comparison circuits 15 and 17 compares the clock signal Clk-FB and the external clock CLK with each other. According to the result of comparison, the rise and the fall counters 14 and 21 are counted up or down and produce counter outputs Ct-R and Ct-F, respectively. In response to the counter outputs Ct-R and Ct-F, the delay adjustment circuits 12 and 20 adjust delays for rise and fall, respectively.

In Japanese Unexamined Patent Application Publication (JP-A) No. 2003-218691 (Patent Document 2), control of a fine adjustment circuit (200 in FIG. 1 of Patent Document 2) is in common for rise and fall. However, a coarse delay portion comprises independent circuits for rise and fall, respectively. Therefore, the above-mentioned problem has not been solved because a doubled circuit scale is required with respect to the coarse delay portion. Further, in Patent Document 2, the fine adjustment circuit is used in common for rise and fall. However, in such a case, no adjustment is carried out on a fall side by the fine adjustment circuit. Therefore, another problem arises that an error is caused to occur on the fall side, as compared with the DLL circuit in Patent Document 1.

Japanese Unexamined Patent Application Publication (JP-A) No. H10-32488 (Patent Document 3) discloses a DLL circuit using only a rise side of a clock. In Patent Document 3, one delay circuit is used in a synchronous mirrored delay circuit which typically uses two delay circuits arranged so that a forward delay value is equal to a backward delay value. However, the technique disclosed in Patent Document 3 uses no fall side and is not applicable to a DLL circuit for establishing synchronization on both rise and fall sides. According to the above-mentioned Patent Documents, a circuit scale is inevitably increased in case of constructing a high-accuracy DLL circuit and no technique is disclosed which is capable of providing a DLL circuit having a small number of elements and high accuracy. Therefore, there still remains a demand for a DLL circuit having a small number of elements and high accuracy.

### SUMMARY OF THE INVENTION

As mentioned above, for the purpose of high-speed data transfer, it is desired to develop a DLL circuit having a small circuit scale and high accuracy. It is therefore an object of the present invention to provide a DLL circuit having a small circuit scale and high accuracy.

For the purpose of accomplishing the above-mentioned object, the present invention essentially employs a technique which will be described hereinunder. It is readily understood that the present invention encompasses applied techniques modified in various manners without departing from the technical purpose of the present invention.

DLL circuits according to this invention are as follows:

(1) A DLL circuit comprising a rise delay adjustment circuit for synchronizing rise of an internal clock with rise of an external clock and a fall delay adjustment circuit for synchronizing fall of an internal clock with fall of an external clock, the fall delay adjustment circuit being supplied with an output from the rise delay adjustment circuit and performing delay adjustment in order to synchronize the fall of the internal clock with the fall of the external clock.

(2) The DLL circuit as described in (1), wherein the rise delay adjustment circuit has a delay adjustment width longer than an external clock cycle and the fall delay adjustment circuit has a delay adjustment width shorter than the external clock cycle.

(3) The DLL circuit as described in (2), wherein the rise delay adjustment circuit produces an internal clock signal delay-adjusted for rise so that a time width between the rise and the fall is shorter by a predetermined time duration than that of the external clock.

(4) The DLL circuit as described in (3), wherein the fall delay adjustment circuit has the delay adjustment width twice as long as the predetermined time duration.

(5) The DLL circuit as described in (2), wherein the fall delay adjustment circuit is supplied with the signal delay-adjusted for the rise of the internal clock by the rise delay adjustment circuit and delays the signal by a predetermined time duration.

(6) The DLL circuit as described in (5), wherein the fall delay adjustment circuit has the delay adjustment width twice as long as the predetermined time duration.

(7) The DLL circuit as described in (2), further comprising a rise phase comparison circuit for detecting a delay difference between the rises of the external clock and the internal clock, a rise counter for counting the result of comparison in the rise phase comparison circuit, a fall phase comparison circuit for detecting a delay difference between the falls of the external clock and the internal clock, and a fall counter for counting the result of comparison in the fall phase comparison circuit, the rise counter alone being operated while the fall counter is stopped until synchronization is established between the rises of the external clock and the internal clock in the rise delay adjustment circuit.

(8) The DLL circuit as described in (2), further comprising a rise phase comparison circuit for detecting a delay difference between the rises of the external clock and the internal clock, a rise counter for counting the result of comparison in the rise phase comparison circuit, a fall phase comparison circuit for detecting a delay difference between the falls of the external clock and the internal clock, and a fall counter for counting the result of comparison in the fall phase comparison circuit, the rise counter and the fall counter being alternately operated.

(9) The DLL circuit as described in (2), further comprising a rise phase comparison circuit for detecting a delay difference between the rises of the external clock and the internal clock, a rise counter for counting the result of comparison in the rise phase comparison circuit, a fall phase comparison circuit for detecting a delay difference between the falls of the external clock and the internal clock, and a fall counter for counting the result of comparison in the fall phase comparison circuit, the rise counter and the fall counter being operated in response to an ACT command.

A DLL circuit of the present invention comprises a rise delay adjustment circuit, a rise phase comparison circuit, a rise counter, a fall delay adjustment circuit, a fall phase comparison circuit, a fall counter, a Mux circuit for synthesizing an ultimate or final internal clock, and an output delay replica circuit. The fall delay adjustment circuit is supplied with an output clock from the rise delay adjustment circuit and adjusts a delay on a fall side with reference to a clock obtained by delay adjustment on a rise side. Therefore, a delay adjustment width on the fall side can be shortened. Because the delay adjustment width is shortened as mentioned above, the fall delay adjustment circuit and the fall counter can be drastically reduced in circuit scale. With the above-mentioned structure of the present invention, it is possible to obtain a DLL circuit having a small circuit scale and high-accuracy.

### BRIEF DESCRIPTION OF THE DRAWINGS

FIG. 1 is a circuit block diagram of a conventional DLL circuit;

FIG. 2 is a time chart of operation in FIG. 1;

FIG. 3 is a circuit block diagram of a DLL circuit according to the present invention;

FIG. 4 is a block diagram of a fall delay adjustment circuit in a first embodiment;

FIG. 5 is a time chart of operation in the first embodiment;

FIG. 6 is a circuit diagram of the fall delay adjustment circuit in FIG. 4;

FIG. 7 is a time chart of operation in FIG. 4;

FIG. 8 is a block diagram of a fall delay adjustment circuit in a second embodiment;

FIG. 9 is a time chart of operation in FIG. 8;

FIG. 10 is a time chart of a counter control in the present invention; and

FIG. 11 is a time chart of another counter control in the present invention.

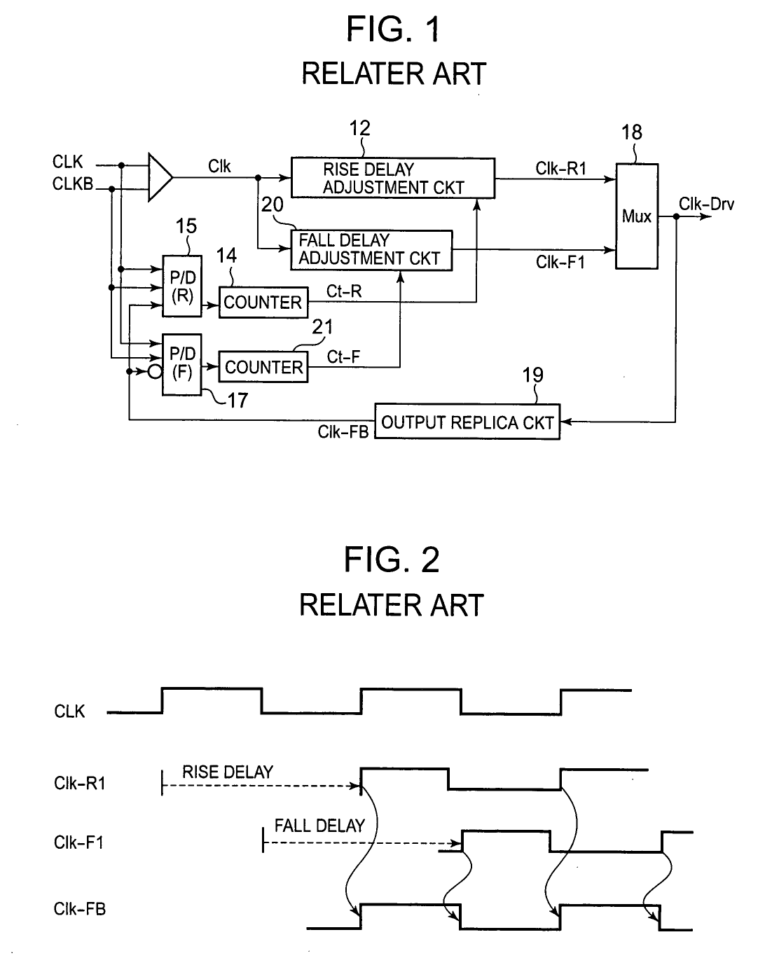

### DESCRIPTION OF EXEMPLARY EMBODIMENTS

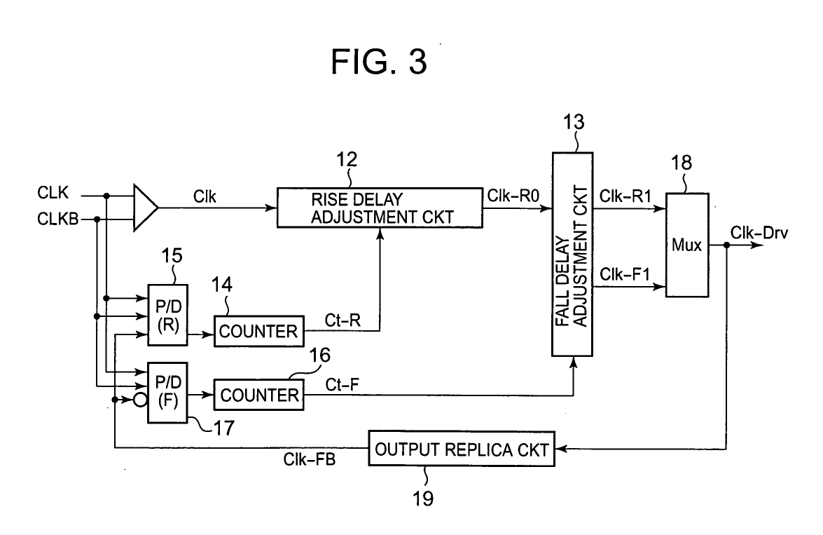

Now, referring to FIG. 3, a basic structure of a DLL circuit of the present invention will be described. FIG. 3 shows a circuit block structure of the DLL circuit of the present invention.

The DLL circuit of the present invention comprises a rise delay adjustment circuit 12, a rise phase comparison circuit 15, a rise counter 14, a fall delay adjustment circuit 13, a fall phase comparison circuit 17, a fall counter 16, a Mux circuit 18 for synthesizing an ultimate or final internal clock, and an output replica circuit 19. The present invention is characterized in that the fall delay adjustment circuit 13 is supplied with an output clock Clk-R0 from the rise delay adjustment circuit 12 instead of an external clock signal. The rise and the fall delay adjustment circuits and delay circuits in the present invention comprise conventional inverters, NAND circuits, or the like and the detailed description thereof will be omitted.

Delay adjustment on a rise side will be described. The rise delay adjustment circuit 12 is supplied with a clock Clk from an input buffer. The input buffer is supplied with an external clock CLK and with an inverted clock CLKB into which the external clock CLK is inverted. The rise delay adjustment circuit 12 performs delay adjustment with reference to a counter output Ct-R from the rise counter 14 to produce the clock Clk-R0. The rise delay adjustment circuit 12 is a delay adjustment circuit having high accuracy and, as a delay-adjustable range, a delay adjustment width not shorter than a clock period. Herein, the rise delay adjustment circuit 12 has the delay adjustment width, for example, on the order of 10 ns and is capable of performing delay adjustment with high accuracy. Further, the rise delay adjustment circuit 12 is arranged so that fall of the clock Clk-R0 is earlier by a predetermined time duration (td) than fall of the clock Clk.

The fall delay adjustment circuit 13 is supplied with the clock Clk-R0 and produces a clock Clk-R1. The clock Clk-R1 is supplied to the Mux circuit 18 to be synthesized and then sent to the output replica circuit 19 to produce a clock Clk-FB. The rise phase comparison circuit 15 compares rise of the clock Clk-FB with rise of an external clock CLK. According to the result of comparison, the rise counter 14 is counted up or down to control the rise delay adjustment circuit 12. The rise counter 14 has, for example, 10 bits in order to count a time width not shorter than the clock period. The delay adjustment on the rise side is performed by the rise delay adjustment circuit 12 having the delay adjustment width on the order of 10 ns not shorter than a clock cycle and the rise counter 14 having a plurality of bits on the order of 10 bits.

Next, delay adjustment on a fall side will be described. The fall delay adjustment circuit 13 is supplied with the clock Clk-R0 from the rise delay adjustment circuit 12 and a counter output Ct-F from the fall counter 16 and produces a clock Clk-F1 obtained by delay adjustment on the fall side. The clock Clk-R0 supplied to the fall delay adjustment circuit 13 has already been subjected to delay adjustment on the rise side. The fall side is set at a timing earlier by a predetermined time duration (td). The predetermined time duration (td) is as small as about several hundreds ps. Therefore, it is possible to reduce a time width of delay adjustment. For example, the time width of delay adjustment may be 200 ps. As a consequence, a fall delay adjustment circuit covering about 10 ns, which has heretofore been required, is no longer necessary and the fall delay adjustment circuit 13 can be implemented by a delay adjustment circuit on the order of several hundreds ps. Thus, the fall delay adjustment circuit 13 can be reduced in circuit scale.

The clock Clk-F1 from the fall delay adjustment circuit 13 is supplied to the Mux circuit 18 to be synthesized and then sent to the output replica circuit 19 to produce the clock Clk-FB. The fall phase comparison circuit 17 compares fall of the clock Clk-FB and fall of the external clock CLK with each other. According to the result of comparison, the fall counter 16 is counted up or down to control the fall delay adjustment circuit 13.

The fall counter 16 can be reduced in number of bits since a difference between the clock Clk-FB and the external clock CLK is small. In case where 10 ns is covered by every step of 25 ps, a 10-bit counter has been required in the conventional technique. On the other hand, in the DLL circuit of the present invention, rise has already been subjected to delay adjustment. Therefore, a difference in delay on the fall side is small so that a delay adjustment width can be reduced to a level on the order of 200 ps. If the delay adjustment width is 200 ps, delay adjustment can be achieved by the use of a 3- or 4-bit counter assuming that the delay adjustment step is 25 ps. As a result, the fall counter 16 can be constructed in a half circuit scale. Thus, the fall counter 16 can be reduced in circuit scale.

As mentioned above, the fall delay adjustment circuit is supplied with the clock which has already been subjected to delay adjustment on the rise side by the rise delay adjustment circuit. Since the supplied clock has already been adjusted on the rise side, a delay difference on the fall side is very small. Therefore, a time width of delay adjustment on the fall side can be reduced. Thus, no independent delay adjustment circuits are provided on the rise and the fall sides and the delay adjustment on the fall side is performed by using the clock signal obtained by delay adjustment on the rise side as an input signal for delay adjustment on the fall side.

With the above-mentioned structure, the delay adjustment width can be as small as on the order of several hundreds ps for the delay adjustment on the fall side. Therefore, the delay adjustment on the fall side can be carried out by the fall delay adjustment circuit 13 having the delay adjustment width on the order of several hundreds ps and the fall counter 16 having 3 or 4 bits. Thus, the fall delay adjustment circuit and the fall counter can be drastically reduced in circuit scale. As a result, a DLL circuit having a small circuit scale and high accuracy can be obtained.

Hereinbelow, the structure and the operation of the DLL circuit of the present invention will be described in detail in connection with several exemplary embodiments.

### First Embodiment

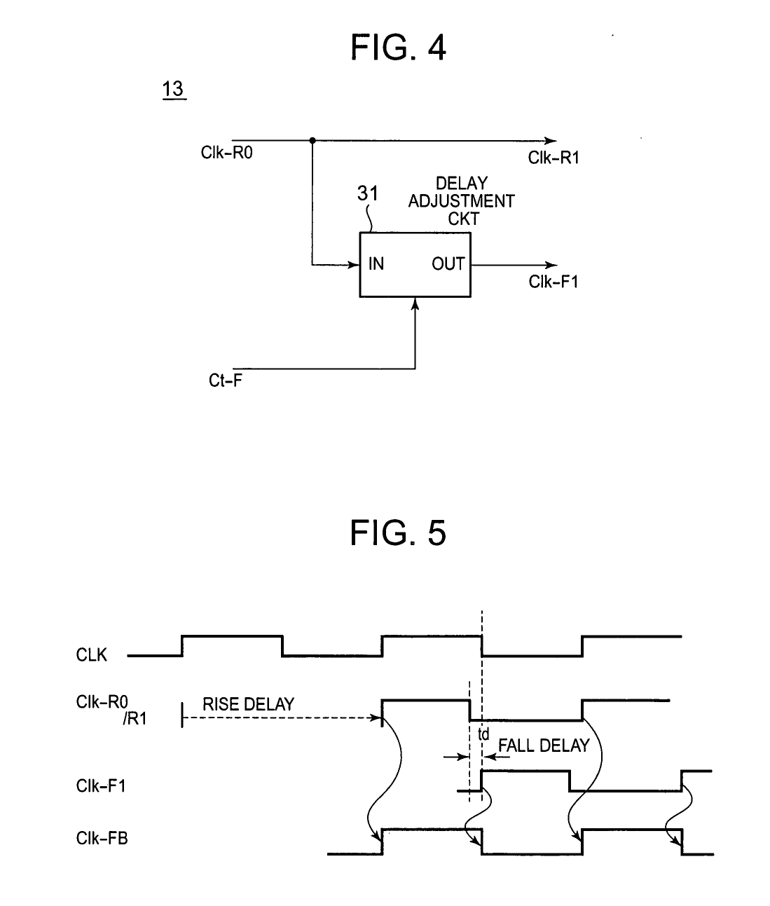

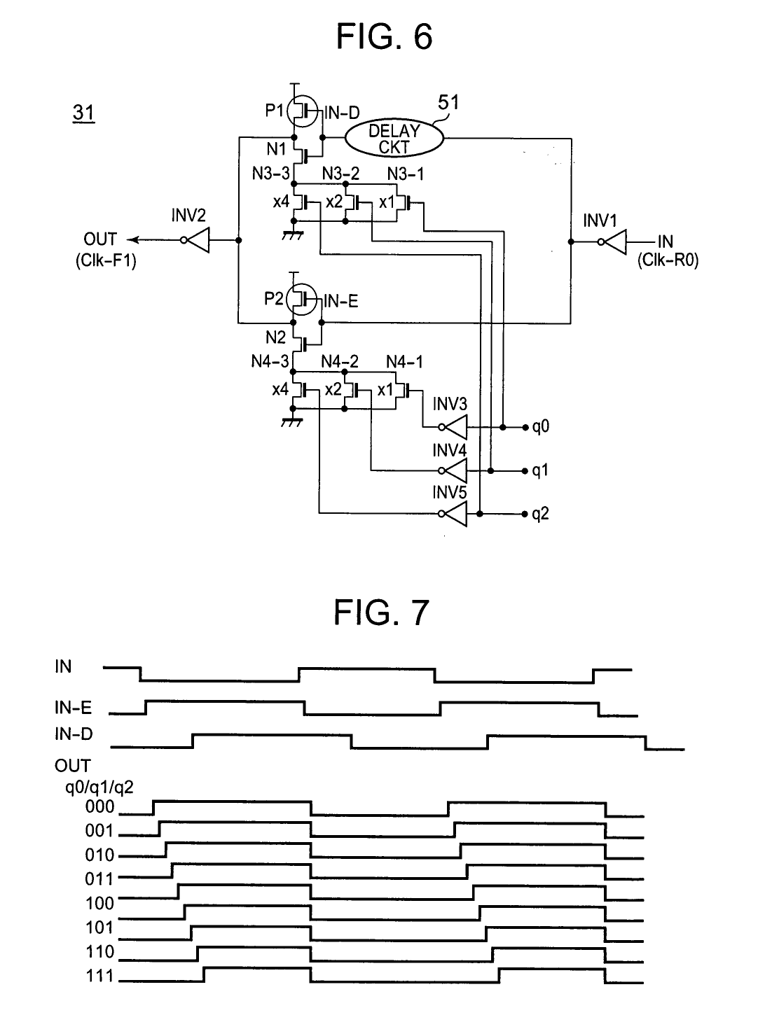

Referring to FIGS. 4 to 7, description will be made of a first example of a circuit structure of the DLL circuit shown in FIG. 3. FIG. 4 is a block diagram of the fall delay adjustment circuit 13 and FIG. 5 is an operation time chart thereof. FIG. 6 is a circuit diagram of a delay adjustment circuit 31 shown in FIG. 4, and FIG. 7 is an operation time chart thereof.

The fall delay adjustment circuit 13 shown in FIG. 4 is supplied with the clock Clk-R0 and the counter output Ct-F and produces the clock Clk-R1 and the clock Clk-F1. On the one hand, the clock Clk-R0 supplied from the rise delay adjustment circuit 12 is directly supplied to the Mux circuit 18 as the clock Clk-R1. The delay adjustment circuit 31 is supplied with the clock Clk-R0 and adjusts the delay of the clock Clk-R0 on the fall side with reference to the counter output Ct-F from the fall counter 16 to produce the clock Clk-F1 which is delivered to the Mux circuit 18. The delay adjustment circuit 31 has a delay adjustment width on the order of several hundreds ps and adjusts the delay of the clock Clk-R0 on the fall side with reference to the counter output Ct-F. The clock Clk-R1 is a clock obtained by delay adjustment on the rise side while the clock Clk-F1 is a clock obtained by delay adjustment on the fall side.

Referring to FIGS. 3 to 5, the block diagram and the time chart of the DLL circuit will be described. The rise delay adjustment circuit 12 performs delay adjustment of the clock Clk on the rise side with reference to the counter output Ct-R of the rise counter 14 to produce the clock Clk-R0. The output clock Clk-R0 of the rise delay adjustment circuit 12 has the fall side earlier by a time duration (td) than the rise side. This can be accomplished, for example, by adjusting a ratio of a load-side Pch transistor and a driver-side Nch transistor of an inverter constructing the rise delay adjustment circuit 12. The clock Clk-R0 is directly supplied to the Mux circuit 18 as the clock Clk-R1.

The clock Clk-R0 is subjected to delay adjustment on the fall side in the fall delay adjustment circuit 13 (namely, the delay adjustment circuit 31) to be produced as the clock Clk-F1. The delay adjustment circuit 31 is supplied with the counter output Ct-F from the fall counter 16 and adjusts the delay on the fall side. In this case, the time duration (td) is approximately adjusted. The rise delay adjustment circuit 12 sets the fall side of the clock Clk-R0 at a timing earlier by the time duration (td) than the rise side. The time duration (td) is preferably a half of the delay adjustment width of the delay adjustment circuit 31. Thus, the amount of adjustment on the fall side can be reduced to a half of the delay adjustment width of the delay adjustment circuit 31.

The Mux circuit 18 synthesizes the clock Clk-R1 obtained by delay adjustment on the rise side and the clock Clk-F1 obtained by delay adjustment on the fall side to produce the clock Clk-FB via the output replica circuit 19. The clock Clk-FB is supplied to the rise and the fall phase comparison circuits 15 and 17 and compared with the clock CLK. In case where there is a delay difference, the rise and the fall counters 14 and 16 are counted up or down. In case where there is no delay difference, the counters 14 and 16 are not counted up or down to produce a constant output. The rise and the fall phase comparison circuits 15 and 17 perform phase-comparison on the rise and the fall sides, respectively. According to the result of comparison, the counter outputs Ct-R and Ct-F are produced from the rise and the fall counters 14 and 16, respectively.

The rise delay adjustment circuit 12 supplied with the counter output Ct-R adjusts the delay of the clock Clk on the rise side to produce the clock Clk-R0 delay-adjusted on the rise side. The fall delay adjustment circuit 13 supplied with the counter output Ct-F adjusts the delay of the clock Clk-R0 on the fall side to produce the clock Clk-F1 delay-adjusted on the fall side. Thus, it is possible to generate the clock Clk-R1 synchronized with the rise of the clock CLK, and the clock Clk-F1 synchronized with the fall of the clock CLK.

Next, referring to FIGS. 6 and 7, the circuit diagram and the time chart of the delay adjustment circuit 31 will be described. Herein, the counter output has 3 bits. However, the number of bits is not particularly limited and may be set to any desired number depending on the delay adjustment width. The delay adjustment circuit 31 is supplied with an input signal IN (specifically, Clk-R0) and produces an output signal OUT (specifically, Clk-F1) obtained by delay adjustment. Delay adjustment of the delay adjustment circuit 31 is controlled by 3-bit counter outputs (q0, q1, and q2) supplied from the fall counter 16. Because the input signal is synchronized on the rise side, the delay adjustment amount of the delay adjustment circuit 31 is as small as several hundreds ps on the fall side and the counter output of 3 bits is sufficient for delay adjustment.

The delay adjustment circuit 31 has an inverter INV1 as an input stage. The inverter INV1 is supplied with the input signal IN (Clk-R0) and produces a signal IN-E which is delivered to a delay circuit 51 and a gate of each of transistors P2 and N2. The transistor P2 has a drain, a source, and the gate which are connected to a drain of the transistor N2, a power source, and the signal IN-E, respectively. The transistor N2 has the drain, a source, and the gate which are connected to the drain of the transistor P2, drains of transistors N4-3, N4-2, and N4-1, and the signal IN-E, respectively. The drains of the transistor P2 and the transistor N2 are connected to each other to produce an output as an input to an inverter INV2.

The transistors N4-1, N4-2, and N4-3 have the drains and sources which are connected in common to the source of the transistor N2 and to a ground potential, respectively. The transistors N4-1, N4-2, and N4-3 have gates supplied with inverted signals which are obtained by inverting the counter outputs (q0, q1, and q2) from the fall counter 16 in inverters INV3, 4, and 5, respectively. Herein, the transistors N4-1, N4-2, and N4-3 are designed to have current driving capabilities in a ratio of 1:2:4. The transistors N4-1, N4-2, and N4-3 are turned on or off in response to the inverted signals of the counter outputs (q0, q1, and q2) from the fall counter 16 to thereby adjust a delay time.

The delay circuit 51 delays the signal IN-E supplied thereto to produce a signal IN-D which is supplied to gates of transistors P1 and N1. The transistor P1 has a drain, a source, and the gate which are connected to a drain of the transistor N1, a power source, and the signal IN-D, respectively. The transistor N1 has the drain, a source, and the gate which are connected to the drain of the transistor P1, drains of transistors N3-3, N3-2, and N3-1, and the signal IN-D, respectively. The drains of the transistor P1 and the transistor N1 are connected to each other to produce an output as an input to the inverter INV2.

The drains and sources of the transistors N3-1, N3-2, and N3-3 are connected in common to the source of the transistor N1 and to a ground potential, respectively. The transistors N3-1, N3-2, and N3-3 have gates supplied with the counter outputs (q0, q1, and q2) from the fall counter 16, respectively. Herein, the transistors N3-1, N3-2, and N3-3 are designed to have current driving capabilities in a ratio of 1:2:4. The transistors N4-1, N4-2, and N4-3 are turned on or off in response to the counter outputs (q0, q1, and q2) from the fall counter 16 to thereby adjust a delay time.

The inverter INV2 is supplied with two outputs from its preceding stage and carries out waveform-shaping to produce an output signal OUT. The delay adjustment circuit 31 changes rise of the input signal IN directly to a low level and changes fall of the input signal IN to a high level with a time difference. For this purpose, assuming that the Nch transistors have the sizes x1, x2, and x4, an operation speed of the delay adjustment circuit 31 is adjusted in 8 (=2³) levels in response to the counter outputs (q0, q1, and q2) from the fall counter 16. With this structure, delay adjustment at a step on the order of several tens ps is enabled.

Referring to the time chart in FIG. 7, an operation of the delay adjustment circuit 31 at the fall will be described. The input signal IN is inverted in the inverter INV1 to become the signal IN-E and the signal IN-D delayed in the delay circuit 51. A delay amount in the delay circuit 51 is a delay adjustment width on the fall side. Since the input signal is synchronized on the rise side, the delay adjustment width on the fall side is several hundreds ps. Preferably, delay adjustment is performed at a center of the delay adjustment width. Therefore, it is preferable that the delay amount of the delay circuit 51 is, for example, twice the time duration (td).

The delay amount of the delay circuit 51 is divided by the counter outputs and delay adjustment is performed. For example, it is assumed that the counter outputs (q0, q1, and q2) from the fall counter 16 are (0, 0, and 0). In this case, the transistors N3-1, N3-2, and N3-3 are in an off state, while the transistors N4-1, N4-2, and N4-3 are in an on state. Therefore, in correspondence to the signal IN-E, the output signal OUT has a high level without being delayed. On the other hand, in case where the counter outputs (q0, q1, and q2) are (1, 1, and 1), the transistors N3-1, N3-2, and N3-3 are in an on state, while the transistors N4-1, N4-2, and N4-3 are in an off state. Therefore, the output signal OUT has a high level in correspondence to the signal IN-D which has been delayed.

Thus, in response to the counter outputs (q0, q1, and q2), the transistors to be activated are switched and the output signal OUT has a high level with a delay time obtained by dividing the delay amount of the delay circuit 51. For example, the input clock Clk-R0 has the fall side earlier by time duration (td) than the rise side so that the delay adjustment amount is approximately equal to td. In case where the delay amount of the delay circuit 51 is, for example, equal to twice the time duration (td), the delay adjustment is performed at a center region thereof. On the rise side, when the input signal IN has a high level, the signal IN-E has a low level. The transistor P2 is turned on so that the operation on the rise side is performed at a fixed time instant in synchronization with the signal IN-E.

The fall delay adjustment circuit of the present embodiment is supplied with the clock which has been delay-adjusted on the rise side by the rise delay adjustment circuit. From the input clock, the fall delay adjustment circuit produces a delayed clock which is delayed by a time required for adjustment. The delay amount between the input clock and the delayed clock can be reduced because the delayed clock is synchronized on the rise side with the input clock so that the delay circuit can be reduced in circuit scale. Further, the delay amount between the input clock and the delayed clock is divided by the counter outputs to thereby perform delay adjustment on the fall side with high accuracy. Furthermore, the number of bits of the counter can also be reduced so that the counter can be reduced in circuit scale. Thus, with the fall delay adjustment circuit of the present embodiment, it is possible to achieve a DLL circuit having a small circuit scale and capable of performing delay adjustment with high accuracy.

### Second Embodiment

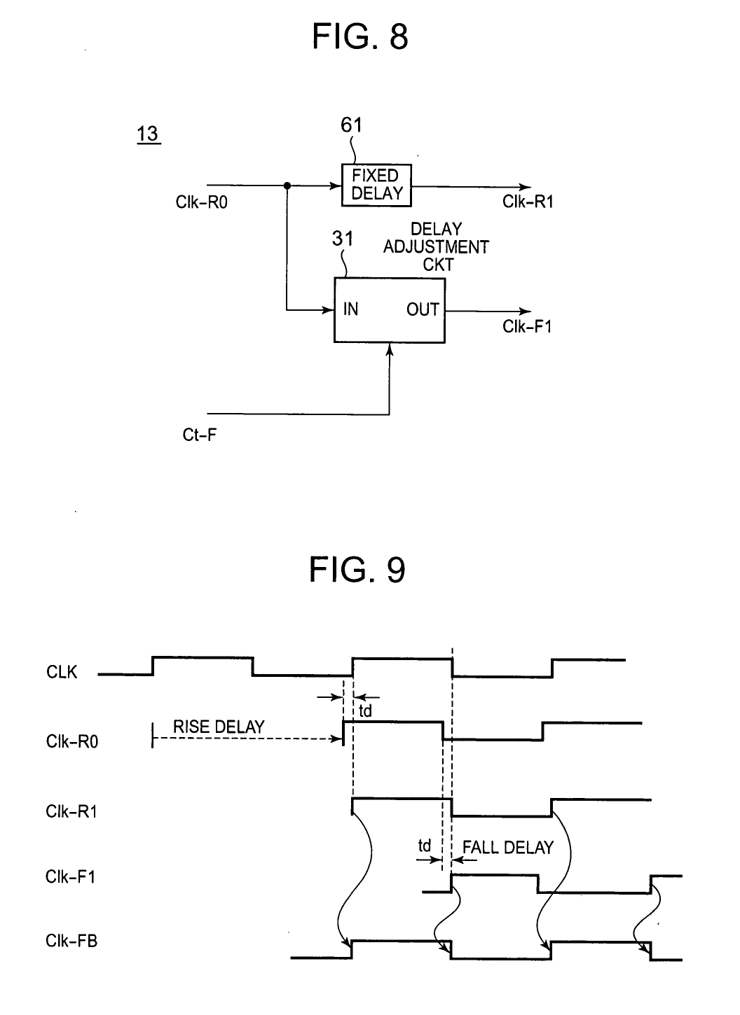

Referring to FIGS. 3, 8, and 9, a second embodiment of the present invention will be described. The embodiment is a second example of circuit structure of the DLL circuit. FIG. 8 shows a second circuit diagram of the delay adjustment circuit 31 and FIG. 9 shows a time chart thereof.

In the second embodiment, a second delay circuit 61 and the second delay adjustment circuit 31 are supplied with the clock Clk-R0 from the rise delay adjustment circuit 12. The second delay circuit 61 delays the clock Clk-R0 by a predetermined time period to produce the clock Clk-R1 which is delivered to the Mux circuit 18. The delay adjustment circuit 31 is supplied with the clock Clk-R0 and adjusts the delay on the fall side in response to the counter output from the fall counter 16 to produce the clock Clk-F1. The delay adjustment circuit 31 is same as that described in the first embodiment.

The rise delay adjustment circuit 12 in the first embodiment gives different delays for rise and fall so that the fall side is earlier by the predetermined time duration (td). On the other hand, the rise delay adjustment circuit 12 of the present embodiment gives the same delay for rise and fall and produces the clock Clk-R0 which is earlier by the predetermined time duration (td) with respect to the clock Clk. The clock Clk-R0 is delayed by the predetermined time duration (td) by the second delay circuit 61 to be produced as the clock Clk-R1. Therefore, the rise of the clock Clk-R1 is synchronized with the rise of the clock CLK. The fall delay adjustment circuit 31 is supplied with the clock Clk-R0 having the fall earlier by the predetermined time duration (td) with respect to the fall of the clock CLK. Therefore, in the manner similar to the first embodiment, the delay adjustment circuit 31 can synchronize the clock Clk-F1 with the fall of the clock CLK.

In the present embodiment, as shown in FIG. 9, the clock Clk-R0 is delayed by the predetermined time duration (td) to be produced as the clock Clk-R1. The delay adjustment circuit, especially a coarse delay adjustment circuit, is constructed by connecting a plurality of stages of same inverters and same NAND circuits, as shown in the conventional example (FIGS. 5 and 6 of Patent Document 1). In case where each of these circuits is simply given a difference between rise and fall, a delay value of coarse delay is increased by increase in number of circuit stages. As a result, a delay difference between rise and fall is also increased. Therefore, only some of the circuits are given a delay difference between rise and fall.

Generally, however, in order to achieve a uniform delay difference between two signals supplied to a fine adjustment circuit, that is, a uniform delay amount per every single step of coarse delay, the same circuits are repeatedly used as delay elements of the coarse delay adjustment circuit. Accordingly, it is preferable to adopt a structure in which the coarse delay adjustment circuit is prepared by the same circuits so that a delay between rise and fall is not given as far as possible, and, as shown in FIG. 8, a fixed delay is given to the rise side. Preferably, the fixed delay has a delay value which is half of the delay adjustment width of the delay adjustment circuit 31. This makes it possible to adjust the fall side with respect to the rise side over a range corresponding to a half of the delay adjustment width of the delay adjustment circuit 31.

In the present embodiment, the rise delay adjustment circuit 12 produces the clock Clk-R0 which is earlier by the predetermined time duration with respect to the clock Clk. The fall delay adjustment circuit 13 delays the rise side by the predetermined time duration to produce the clock Clk-R1 synchronized with rise of the clock CLK. On the fall side, in the manner similar to the first embodiment, the clock Clk-F1 synchronized with fall of the clock CLK is produced. In the present embodiment also, the DLL circuit can be constructed by delay circuits and counters in a small circuit scale like in the first embodiment. With the fall delay adjustment circuit of the present embodiment, it is possible to achieve the DLL circuit having a small circuit scale and capable of performing delay adjustment on the fall side with high accuracy.

### Third Embodiment

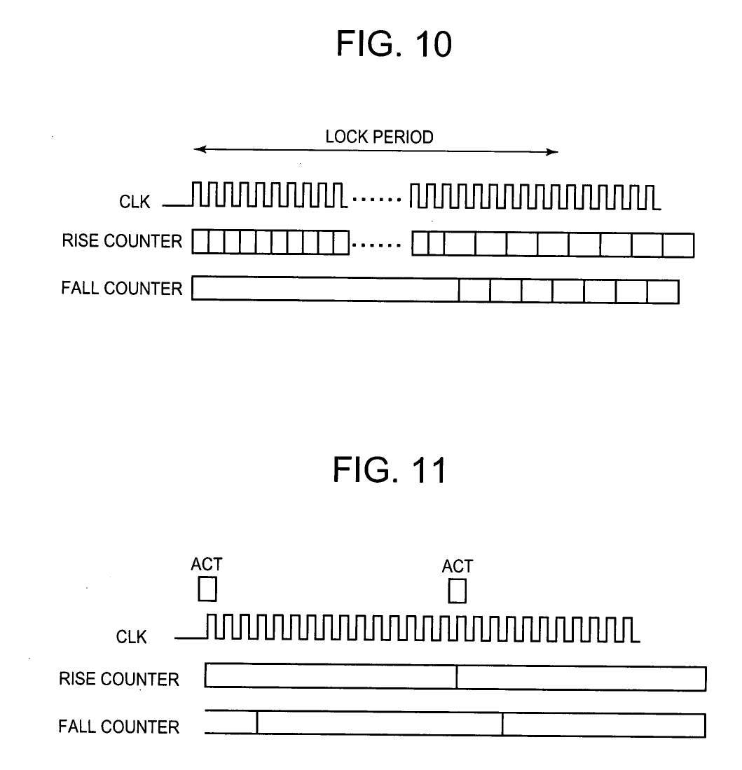

Referring to time charts of FIGS. 10 and 11, a counter control method of the DLL circuit according to a third embodiment will be described.

FIG. 10 is a time chart including a time point when a clock is out of synchronization, for example, upon turning on a power source. The DLL circuit of the present invention synchronizes the fall side by the use of the clock which has been synchronized on the rise side. Therefore, it is preferable in the time chart that, in a state where synchronization on the rise side is established, the fall side is synchronized. As shown in FIG. 10, in a first clock cycle, the fall counter is stopped and delay adjustment is performed only by the rise counter. At a time point when the rise side approaches a locked state by several cycles of adjustment, the fall counter is operated. The time point when the rise side approaches the locked state means a time point when the clock Clk-FB and the clock CLK are approximately synchronized with each other. The time point when the rise side approaches the locked state can be detected, for example, by detecting little or no change in counting up or down of the counter.

From the time point when the rise side approaches the locked state, the fall side is operated also. The delay adjustment is performed by alternately operating the fall side, the rise side, and the fall side. When the rise side is adjusted, the delay on the fall side sharing the delay is also shifted. Therefore, alternate adjustment is preferable. The adjustment is herein performed at every clock cycle, but may be performed at every several clock cycles. Alternatively, the adjustment may be alternately performed at every clock cycle until the DLL circuit approaches the locked state and at every several cycles after the locked state is established.

In FIG. 10, the counters are operated in synchronization with the clock CLK. Alternatively, for example, a DRAM may have a structure in which the counters are operated at every ACT command as shown in FIG. 11. In such a case, the adjustment is performed by making the clock cycle correspond to an ACT cycle. In case where the counters are updated at every ACT command as shown in FIG. 11, there is a structure in which rise is first adjusted and, after the result of adjustment of rise is reflected in the delay, for example, after 3 or 4 cycles, the fall counter is updated. In this case, the counters are updated at a higher frequency as compared with the structure in which the counters are alternately updated at every ACT command. Therefore, the DLL circuit is expected to have higher accuracy.

In the DLL circuit of the present invention, the fall side is adjusted according to the clock adjusted on the rise side. When the rise side is adjusted, the delay on the fall side sharing the delay is also shifted. Therefore, at first, only the rise side is adjusted and adjustment on the fall side is stopped. It is preferable that, in a state where the rise side approaches the locked state, adjustment is alternately performed on the fall side, the rise side, and the fall side. Further, an operation interval between the rise side and the fall side can be set not only by the clock but also by combining the clock and the ACT command.

Hereinbefore, description has been made in detail about the present invention in connection with the embodiments. However, the present invention is not limited to the foregoing embodiments and various modifications may be made without departing from the scope of the invention. It will readily be understood that the present invention encompasses such modifications. For example, in the description of the present invention, the rise delay adjustment circuit first synchronizes the rise side and supplies its output to the fall delay adjustment circuit. Alternatively, the fall delay adjustment circuit may first synchronize the fall side and supply its output to the rise delay adjustment circuit. In this case also, an operation can be performed in the similar manner and the rise delay adjustment circuit and the rise counter can be reduced in circuit scale. Thus, it is also possible to replace the operations on the rise and the fall sides with each other. It will readily be understood that such replacement is encompassed in the present invention.

What is claimed is:

1. A DLL circuit comprising a rise delay adjustment circuit for synchronizing rise of an internal clock with rise of an external clock and a fall delay adjustment circuit for synchronizing fall of an internal clock with fall of an external clock, said fall delay adjustment circuit being supplied with an output from said rise delay adjustment circuit and performing delay adjustment in order to synchronize the fall of the internal clock with the fall of the external clock.

2. The DLL circuit as claimed in claim 1, wherein said rise delay adjustment circuit has a delay adjustment width longer than an external clock cycle and said fall delay adjustment circuit has a delay adjustment width shorter than the external clock cycle.

3. The DLL circuit as claimed in claim 2, wherein said rise delay adjustment circuit produces an internal clock signal delay-adjusted for rise so that a time width between the rise and the fall is shorter by a predetermined time duration than that of the external clock.

4. The DLL circuit as claimed in claim 3, wherein said fall delay adjustment circuit has the delay adjustment width twice as long as said predetermined time duration.

5. The DLL circuit as claimed in claim 2, wherein said fall delay adjustment circuit is supplied with the signal delay-adjusted for the rise of the internal clock by said rise delay adjustment circuit and delays the signal by a predetermined time duration.

6. The DLL circuit as claimed in claim 5, wherein said fall delay adjustment circuit has the delay adjustment width twice as long as said predetermined time duration.

7. The DLL circuit as claimed in claim 2, further comprising a rise phase comparison circuit for detecting a delay difference between the rises of the external clock and the internal clock, a rise counter for counting the result of comparison in said rise phase comparison circuit, a fall phase comparison circuit for detecting a delay difference between the falls of the external clock and the internal clock, and a fall counter for counting the result of comparison in said fall phase comparison circuit, said rise counter alone being operated while said fall counter is stopped until synchronization is established between the rises of the external clock and the internal clock in said rise delay adjustment circuit.

8. The DLL circuit as claimed in claim 2, further comprising a rise phase comparison circuit for detecting a delay difference between the rises of the external clock and the internal clock, a rise counter for counting the result of comparison in said rise phase comparison circuit, a fall phase comparison circuit for detecting a delay difference between the falls of the external clock and the internal clock, and a fall counter for counting the result of comparison in said fall phase comparison circuit, said rise counter and said fall counter being alternately operated.

9. The DLL circuit as claimed in claim 2, further comprising a rise phase comparison circuit for detecting a delay difference between the rises of the external clock and the internal clock, a rise counter for counting the result of comparison in said rise phase comparison circuit, a fall phase comparison circuit for detecting a delay difference between the falls of the external clock and the internal clock, and a fall counter for counting the result of comparison in said fall phase comparison circuit, said rise counter and said fall counter being operated in response to an ACT command.
